(19) United States
(12) Patent Application Publication
(10) Pub. No.: US 2010/0117728 A1
(43) Pub. Date: May 13, 2010

(54) Signal Amplifiers Having Communications Paths that Automatically Terminate to a Matched Termination in Response to a Power Interruption and Related Methods

(76) Inventor: Robert Ryan Riggsby, Hickory, NC (US)

Correspondence Address: MYERS BIGEL SIBLEY & SAJOVEC, P.O. BOX 37428, RALEIGH, NC, 27612, US

(21) Appl. No.: 12/689,267

(22) Filed: Jan. 19, 2010

Related U.S. Application Data
(63) Continuation-in-part of application No. 12/208,675, filed on Sep. 11, 2008.
Application No. 12/208,675 is a continuation-in-part of application No. 11/077,802, filed on Mar. 10, 2005, now abandoned.
(60) Provisional application No. 61/175,191, filed on May 4, 2009.

(51) Int. Cl. H03F 3/68

(52) U.S. Cl. 330/124 R; 333/101

(57) ABSTRACT

RF signal amplifiers are provided that include an RF input port, a first RF output port, a second RF output port and a power input for receiving electrical power. These amplifiers further include a directional coupler having an input that is coupled to the RF input port, a first output and a second output. The second output of the directional coupler is connected to the second RF output port via a non-interruptible communication path. A first switching device having an input, a first output and a second output is also provided. The second output of the first switching device is coupled to a first matched termination. A first diplexer is provided that is coupled between the first output of the directional coupler and the input of the first switching device. A first power amplifier is coupled to the first output of the first switching device, and a second diplexer is coupled between an output of the first power amplifier and the first RF output port. The first switching device is configured to pass signals received at the input to the first switching device to the first output of the first switching device when electrical power is received at the power input and is further configured to terminate signals received at the input to the first switching device through the second output of the first switching device when an electrical power feed to the power input is interrupted.

### CROSS-REFERENCE TO RELATED APPLICATIONS

This application claims priority under 35 U.S.C. §120 as a continuation-in-part application of U.S. patent application Ser. No. 12/208,675, filed Sep. 11, 2008, which in turn claims priority under 35 U.S.C. §120 as a continuation-in-part application of U.S. patent application Ser. No. 11/077,802, filed Mar. 10, 2005. This application further claims priority under 35 U.S.C. §119 to U.S. Provisional Patent Application Ser. No. 61/175,191, filed May 4, 2009. The disclosure of each of the above applications is hereby incorporated by reference herein in its entirety.

### FIELD OF THE INVENTION

The present invention is directed to technology for providing non-interruptible communication.

### BACKGROUND

In recent years, the rise of the Internet and other online communication methods have rapidly transformed the manner in which electronic communications take place. Today, rather than relying on prior-generation switched telephone communication arrangements, many service providers are turning to modern Internet Protocol (IP) based communication networks. Such networks can provide flexibility in facilitating the transmission of voice, data, video, and other information at great speeds.

As a result, many consumers now have the option of conducting telephone conversations, receiving and sending information for interactive video, and communicating over the Internet—all through a single RF connection with the consumer's service provider. However, in order to support these various services, the RF signal received from the service provider (approximately 5 dBmV/channel) may require amplification by an RF amplifier in order to properly service the various communication ports maintained by a consumer.

Unfortunately, if power to the RF amplifier is interrupted, some or all of these services may become unavailable. Although such interruptions may be tolerated by consumers in relation to certain non-essential services, interruptions to other services may be unacceptable. For example, consumers relying on IP-based emergency communications (i.e., 911 service) can be left without such services during power interruptions.

In order to remedy this problem, some consumers may be inclined to acquire a dedicated switched telephone line to provide emergency services during power interruptions. Nevertheless, such an option can require the consumer to incur additional costs and fails to capitalize on the advantages offered by IP-based communication.

### SUMMARY

Pursuant to embodiments of the present invention, bi-directional RF signal amplifiers are provided that include an RF input port, a first RF output port, a second RF output port and a power input for receiving electrical power. The second RF output port may be a voice-over-IP RF output port. These amplifiers further include a directional coupler having an input that is coupled to the RF input port, a first output and a second output. The second output of the directional coupler is connected to the second RF output port via a non-interruptible communication path. A first switching device having an input, a first output and a second output is also provided. The second output of the first switching device is coupled to a first matched termination. A first diplexer is provided that is coupled between the first output of the directional coupler and the input of the first switching device. A first power amplifier is coupled to the first output of the first switching device, and a second diplexer is coupled between an output of the first power amplifier and the first RF output port. In these amplifiers, the first switching device is configured to pass signals received at the input to the first switching device to the first output of the first switching device when electrical power is received at the power input and is further configured to terminate signals received at the input to the first switching device through the second output of the first switching device when an electrical power feed to the power input is interrupted.

In some embodiments, the bi-directional RF signal amplifier may further include a second switching device and a second power amplifier that are coupled in series between the first and second diplexers. In such embodiments, the second switching device may have a first output that is coupled to an input of the second power amplifier and a second output that is coupled to a second matched termination. The first and second matched terminations may each be a resistor that is terminated to a ground voltage. The bi-directional RF signal amplifier may also include a power regulation circuit that receives electrical power from the power input and that outputs a power supply voltage. This power supply voltage may be coupled to the first power amplifier, the second power amplifier, the first switching device and the second switching device.

In some embodiments, the directional coupler may evenly split an input signal between its first output and its second output. In other embodiments, the directional coupler may unevenly split an input signal so as to pass more signal energy to its first output than is passed to its second output. The bi-directional RF signal amplifier may also include a power dividing circuit having an input and a plurality of outputs. This power dividing circuit may be located between the second diplexer and the first RF output port.

Pursuant to further embodiments of the present invention, RF signal amplifiers are provided that include an RF input port, an RF output port, and a switching device having an input that is coupled to the RF input port, a first output and a second output. The second output of the switching device is coupled to a matched termination, and a first power amplifier is coupled between the first output of the switching device and the RF output port. These signal amplifiers further include a power input for receiving electrical power, and the switching device is configured to couple the RF input port to the first output of the switching device when electrical power is received at the power input, and to couple the RF input port to the second output of the switching device when an electrical power feed to the power input is interrupted. In some embodiments, the first matched termination may be resistor that is terminated to a ground voltage.

In some embodiments, an input of the first power amplifier is coupled to the first output of the switching device, and an output of the first power amplifier is coupled to the RF output port. In other embodiments, an input of the first power amplifier is coupled to the RF output port, and an output of the first power amplifier is coupled to the first output of the switching device. In some embodiments, the RF signal amplifier further includes a first diplexer that is coupled between the first output of the switching device and an input to the first power amplifier and a second diplexer that is coupled between an output of the first power amplifier and the RF output port. The RF signal amplifier may also include a second power amplifier having an input that is coupled to the second diplexer and an output that is coupled to the first diplexer.

Pursuant to still further embodiments of the present invention, methods of automatically terminating an RF signal amplifier are provided, where the RF signal amplifier comprises a power amplifier and a switching device having a switch input that is coupled to the cable television network, a first switch output that is coupled to the power amplifier and a second switch output that is coupled to a matched termination (e.g., a resistor that is terminated to a ground voltage). Pursuant to these methods, an input of the RF signal amplifier is coupled to a cable television network. The switching device is automatically switched to connect the switch input from the first switch output to the second switch output in response to an electrical power feed to the RF signal amplifier being interrupted. In some embodiments, the switching device may be automatically switched to connect the switch input from the second switch output to the first switch output in response to the electrical power feed to the RF signal amplifier being restored.

### BRIEF DESCRIPTION OF THE DRAWINGS

FIG. 1 is a block diagram of a bi-directional RF signal amplifier employing a directional coupler for facilitating a non-interruptible communication port, in accordance with embodiments of the present invention.

FIG. 2 is a block diagram of a bi-directional RF signal amplifier employing a non-latching relay and a directional coupler for facilitating a non-interruptible communication port, in accordance with embodiments of the present invention.

FIGS. 3a and 3b are block diagrams of bi-directional RF signal amplifiers employing a plurality of non-latching relays for facilitating a non-interruptible communication port, in accordance with embodiments of the present invention.

FIGS. 4a and 4b are a circuit schematic diagram of a bi-directional RF signal amplifier employing a directional coupler for facilitating a non-interruptible communication port, in accordance with embodiments of the present invention.

FIGS. 5a and 5b are a circuit schematic diagram of a bi-directional RF signal amplifier employing a non-latching relay and a directional coupler for facilitating a non-interruptible communication port, in accordance with embodiments of the present invention.

FIGS. 6a and 6b are a circuit schematic diagram of a bi-directional RF signal amplifier employing a plurality of non-latching relays for facilitating a non-interruptible communication port, in accordance with embodiments of the present invention.

FIG. 7 is a block diagram of a bi-directional RF signal amplifier employing a terminated non-latching relay and a directional coupler for facilitating a non-interruptible communication port, in accordance with embodiments of the present invention.

FIG. 8 is a flow chart diagram illustrating methods of providing a non-interruptible communication path through a signal amplifier according to embodiments of the present invention.

FIG. 9a is a block diagram of a bi-directional RF signal amplifier employing an integrated non-latching relay and amplifier in the forward path for facilitating a non-interruptible communication port, in accordance with embodiments of the present invention.

FIG. 9b is a block diagram of a bi-directional RF signal amplifier employing an integrated non-latching relay and amplifier in both the forward and reverse paths for facilitating a non-interruptible communication port, in accordance with embodiments of the present invention.

FIG. 10 is a block diagram of a bi-directional RF signal amplifier employing at least one terminated integrated circuit switch and a directional coupler for facilitating a non-interruptible communication port, in accordance with embodiments of the present invention.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, etc.).

In accordance with various embodiments set forth in the present disclosure, a bi-directional RF signal amplifier can be provided with a non-interruptible communication port for maintaining communication in the event of power failure. In various embodiments, the amplifier may receive RF signals from a service provider or any other appropriate signal source through an input port.

For example, in residential applications, an amplifier in accordance with various embodiments of the present disclosure may receive a composite RF signal of approximately 5 dBmV/channel in the range of approximately 5-1002 MHz comprising information for telephone, cable television (CATV), Internet, VoIP, and/or data communication from a service provider. The amplifier may increase the signal to a more useful level of approximately 20 dBmV/channel and pass the amplified signal to one or more devices in communication with the amplifier through various output ports. Such devices may include, but need not be limited to: televisions, modems, telephones, computers, and/or other communication devices known in the art. In the event of power failure, an unamplified signal may still be passed through a communication path between the service provider and the communication device.

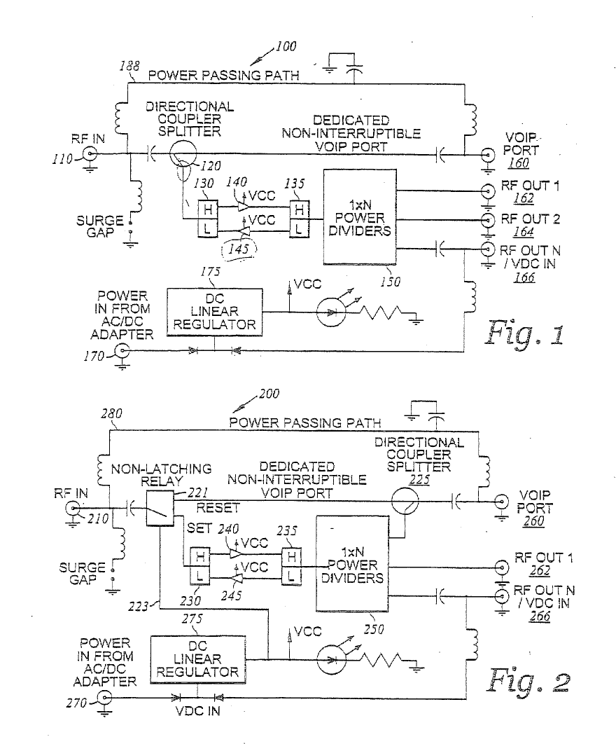

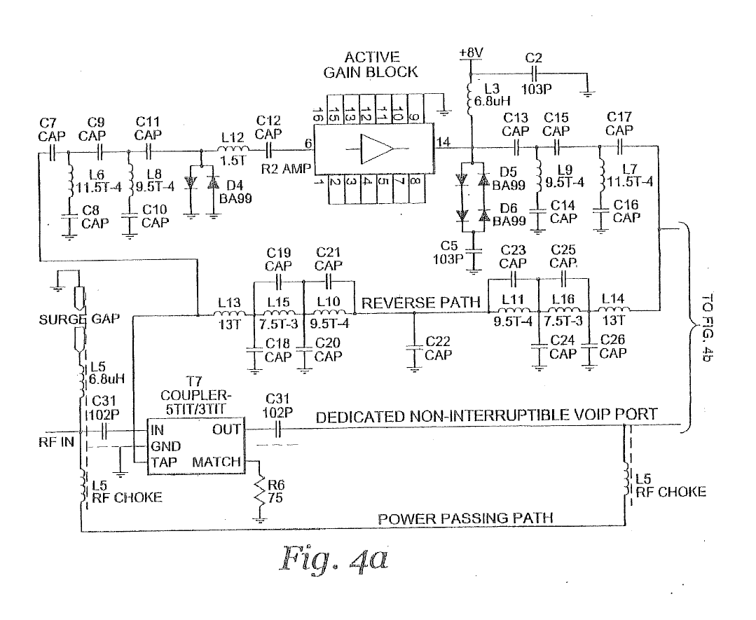

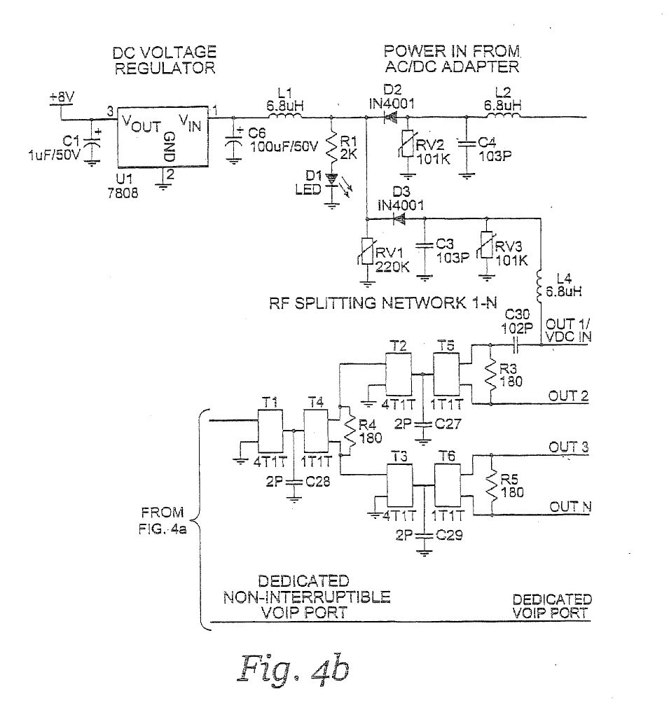

FIGS. 1, 2, 3a, 3b, 7, 9a, 9b and 10 illustrate various embodiments of such an amplifier. Schematic representations of the embodiments of FIGS. 1, 2, and 3a are set forth in FIGS. 4a/4b, 5a/5b, and 6a/6b, respectively.

FIG. 1 illustrates a block diagram of a bi-directional RF signal amplifier 100 employing a directional coupler for facilitating a non-interruptible communication port 160. As illustrated, amplifier 100 can support a plurality of bi-directional communication ports for sending and receiving RF signals to and from a variety of signal sources and destinations.

A bi-directional RF input port 110 can be provided for receiving RF signals from a service provider, or any other appropriate signal source. Input port 110 can also pass output signals in the reverse direction from the amplifier 100 through the port 110 to the service provider or other signal source.

A plurality of bi-directional output ports 160, 162, 164, and 166 can also be provided by amplifier 100 for passing RF signals from the amplifier 100 to one or more devices in communication with the output ports, and vice versa. It will be appreciated that any appropriate device that may advantageously send and/or receive an RF signal may be placed in communication with one or more of the various output ports. For example, it is contemplated that telephone, CATV, Internet, VoIP, and/or data communication devices may be placed in such communication with a service provider where the amplifier 100 is installed in the residence of a subscriber. However, it will further be appreciated that any desired combination of these and/or other devices may be used where appropriate.

Signals received through input port 110 can be passed through a first communication path between input port 110 and output ports 162, 164, and/or 166. Specifically, the signals can be fed through a passive directional coupler 120 to a high/low diplexer 130 for separating the high frequency input signal from any low frequency output signal incident in the reverse direction. In various embodiments, diplexer 130 can filter the signals in a manner such that signals with frequencies greater than approximately 45-50 MHz are passed as high frequency input signals received from port 110, while signals with frequencies lower than such range are passed in the reverse direction as low frequency output signals received from ports 162, 164, or 166.

The high frequency input signals filtered by diplexer 130 can be amplified by individual amplifier 140, and passed to high/low diplexer 135 where they are combined with the output signals. The recombined signal can then be provided to power dividers 150, where it is distributed to any of ports 162, 164, and/or 166.

Turning now to the reverse signal flow through the first communication path of amplifier 100, signals received by the amplifier 100 from devices in communication with ports 162, 164, and/or 166 can be passed to power dividers 150 where they are combined into a composite output signal. The output signal can be fed through high/low diplexer 135 for separating the low frequency output signal from any high frequency input signal incident in the forward direction. As previously discussed in relation to diplexer 130, the diplexer 135 can filter the signals such that signals with frequencies greater than approximately 45-50 MHz are passed in the forward direction as high frequency signals received from port 110, while signals with frequencies lower than such range are passed in the reverse direction as low frequency signals received from ports 162, 164, and/or 166.

The low frequency output signals filtered by diplexer 135 can be amplified by individual amplifier 145, and passed to high/low diplexer 130 where they are combined with the input signals. In various embodiments, individual amplifier 145 can optionally be omitted from amplifier 100. The recombined signal can then be provided to coupler 120 where it is passed to port 110 for output to a service provider or other entity in communication with port 110.

As illustrated, amplifier 100 can further provide a power passing path 188, allowing power to be transmitted between ports 110 and 160.

During normal operation, the amplifier 100 can be powered from a power input port 170 and/or power that is reverse fed through RF OUT N/VDC IN port 166. In a typical installation at a subscriber's residence, it is contemplated that amplifier 100 may be powered by an AC/DC adapter receiving power provided by the residence (for example, 100-230 VAC, 50/60 Hz). As illustrated in FIG. 1, the power received from either power input can be provided to a voltage regulator 175 which supplies an operating voltage VCC to individual amplifiers 140 and/or 145.

In the event that power to voltage regulator 175 is interrupted, voltage regulator 175 will be unable to provide operating voltage VCC to individual amplifiers 140 and/or 145. As a result, individual amplifier 140 will not function to amplify the input signals received through port 110 for proper distribution to the various output ports 162, 164, and/or 166. Similarly, individual amplifier 145 also will not function to amplify the output signals received from ports 162, 164, and/or 166.

In response to this situation, amplifier 100 further provides a second communication path—a path between input port 110 and output port 160. In this regard, a dedicated non-interruptible port 160 can communicate with port 110 through coupler 120. Using this second communication path between ports 110 and 160 through coupler 120, signals can still be passed between a device in communication with port 160 and a service provider in communication with port 110. It will be appreciated that although the second communication path of amplifier 100 does not necessarily amplify the input or output signals, the path can nevertheless permit communication of at least one or more services, such as emergency 911 telephone service.

It will be appreciated that the use of the second communication path between ports 110 and 160 can provide a significant advantage in ensuring the availability of communication to at least one communication device in the event of power failure. A communication device in communication with port 160 (such as a VoIP compatible device, or other device) can further be provided with backup battery power to maintain the operation of the communication device. As discussed above, a schematic representation of the amplifier 100 of FIG. 1 is set forth in FIGS. 4a and 4b.

FIG. 2 illustrates a block diagram of a bi-directional RF signal amplifier 200 employing a non-latching relay 221 and a directional coupler 225 for maintaining a non-interruptible communication port 260. As illustrated, amplifier 200 can support a plurality of bi-directional communication ports for sending and receiving RF signals to and from a variety of signal sources and destinations.

Similar to amplifier 100 previously discussed herein, amplifier 200 includes a bi-directional RF input port 210 for receiving RF signals from a service provider, or any other appropriate signal source. Input port 210 can also pass output signals in the reverse direction from the amplifier 200 through the port 210 to the service provider or other signal source.

A plurality of bi-directional output ports 260, 262, and 266 can also be provided by amplifier 200 for passing RF signals from the amplifier 200 to one or more devices in communication with the output ports, and vice versa. Similar to amplifier 100, it will be appreciated that any appropriate device that may advantageously send and/or receive an RF signal may be placed in communication with one or more of the various output ports of amplifier 200. For example, it is contemplated that telephone, CATV, Internet, VoIP, and/or data communication devices may be placed in such communication where the amplifier 200 is installed in the residence of a subscriber. However, it will further be appreciated that any desired combination of these and/or other devices may be used where appropriate.

Signals received through input port 210 can be passed through a first communication path between input port 210 and output ports 260, 262, and/or 266. Specifically, the signals can be fed through a SPDT non-latching relay 221 to a high/low diplexer 230 for separating the high frequency input signal from any low frequency output signal incident in the reverse direction. In various embodiments, diplexer 230 can filter the signals in a manner such that signals with frequencies greater than approximately 45-50 MHz are passed as high frequency input signals received from input port 210, while signals with frequencies lower than such range are passed in the reverse direction as low frequency output signals received from ports 260, 262, or 266.

The high frequency input signals filtered by diplexer 230 can be amplified by individual amplifier 240, and passed to high/low diplexer 235 where they are combined with the output signals. The recombined signal can then be provided to power dividers 250, where it is distributed to any of ports 260, 262, and/or 266.

Turning now to the reverse signal flow through the first communication path of amplifier 200, signals received by the amplifier 200 from devices in communication with ports 262 and/or 266 can be passed to power dividers 250 where they are combined into a composite output signal. Signals received through port 260 can be passed to power dividers 250 through passive directional coupler 225 and also combined into the composite signal. The output signal can be fed through high/low diplexer 235 for separating the low frequency output signal from any high frequency input signal incident in the forward direction. As previously discussed in relation to diplexer 230, the diplexer 235 can filter the signals such that signals with frequencies greater than approximately 45-50 MHz are passed in the forward direction as high frequency signals received from port 210, while signals with frequencies lower than such range are passed in the reverse direction as low frequency signals received from ports 260, 262, and/or 266.

The low frequency output signals filtered by diplexer 235 can be amplified by individual amplifier 245, and passed to high/low diplexer 230 where they are combined with the input signals. In various embodiments, individual amplifier 245 can optionally be omitted from amplifier 200. The recombined signal can then be provided to non-latching relay 221 where it is passed to port 210 for output to a service provider or other entity in communication with port 210.

As illustrated, amplifier 200 can further provide a power passing path 280, allowing power to be transmitted between ports 210 and 260.

During normal operation, the amplifier 200 can be powered from a power input port 270 and/or power that is reverse fed through RF OUT N/VDC IN port 266. In a typical installation at a subscriber's residence, it is contemplated that amplifier 200 may be powered by an AC/DC adapter receiving power provided by the residence (for example, 100-230 VAC, 50/60 Hz). As illustrated in FIG. 2, the power received from either power input can be provided to a voltage regulator 275 which supplies an operating voltage VCC to individual amplifiers 240 and/or 245.

In the event that power to voltage regulator 275 is interrupted, voltage regulator 275 will be unable to provide operating voltage VCC to individual amplifiers 240 and/or 245. As a result, individual amplifier 240 will not function to amplify the input signals received through port 210 for proper distribution to the various output ports 260, 262, and/or 266. Similarly, individual amplifier 245 also will not function to amplify the output signals received from ports 260, 262, and/or 266.

Accordingly, amplifier 200 further provides a second communication path between input port 210 and output port 260. In this regard, a dedicated non-interruptible port 260 can communicate with port 210 through relay 221 and coupler 225. As illustrated, amplifier 200 provides a VCC path 223 to relay 221. When power (i.e. VCC) is interrupted, the relay 221 will be caused to switch from the normal signal path in the “set” position, to the non-interruptible signal path in the “reset” position or vice versa. As a result, using the non-interruptible signal path between ports 210 and 260 through relay 221 and coupler 225, signals can still be passed between a device in communication with port 260 and a service provider in communication with port 210. It will be appreciated that although the second communication path of amplifier 200 does not necessarily amplify the input or output signals, the path can nevertheless permit communication of at least one or more services, such as emergency 911 telephone service.

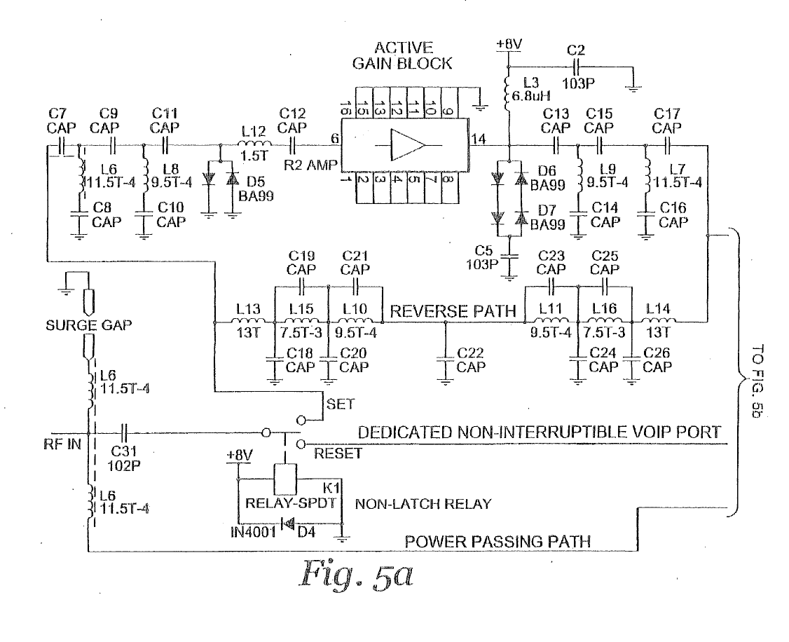

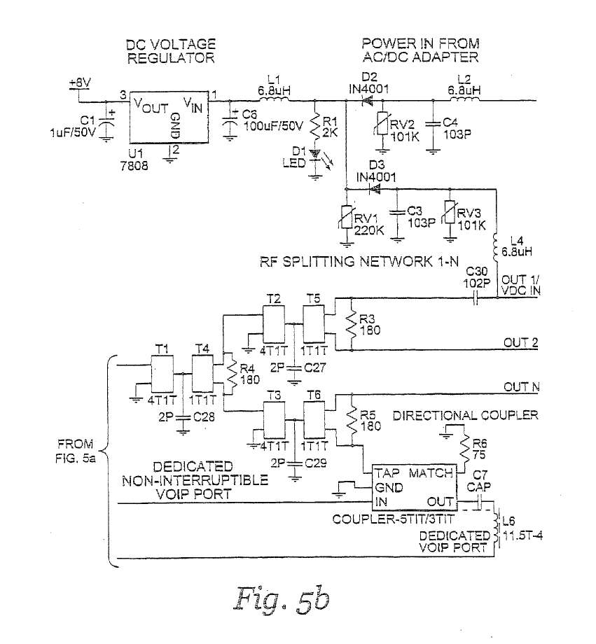

It will be appreciated that the use of the second communication path between ports 210 and 260 can provide a significant advantage in ensuring the availability of communication to at least one communication device in the event of power failure. A communication device in communication with port 260 (such as a VoIP compatible device, or other device) can further be provided with backup battery power to maintain the operation of the communication device. As discussed above, a schematic representation of the amplifier 200 of FIG. 2 is set forth in FIGS. 5a and 5b.

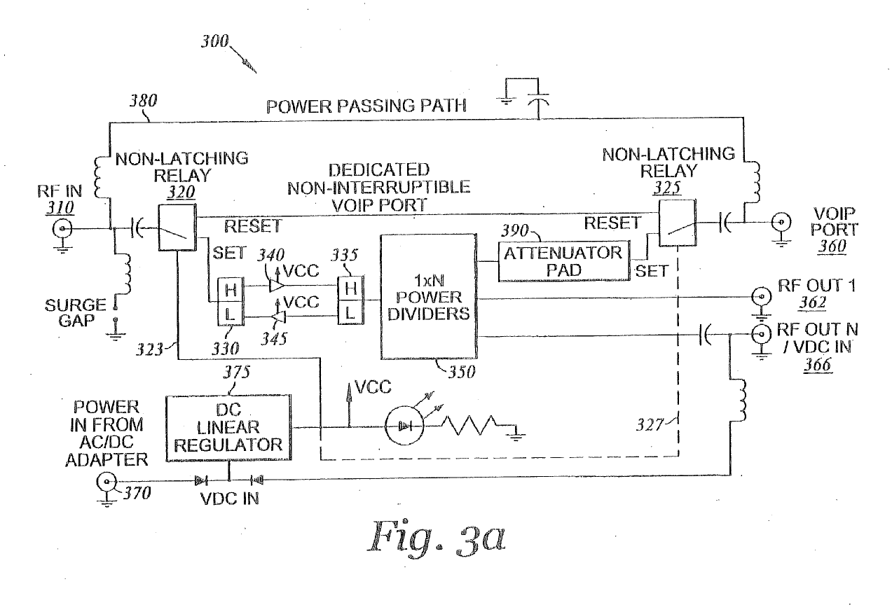

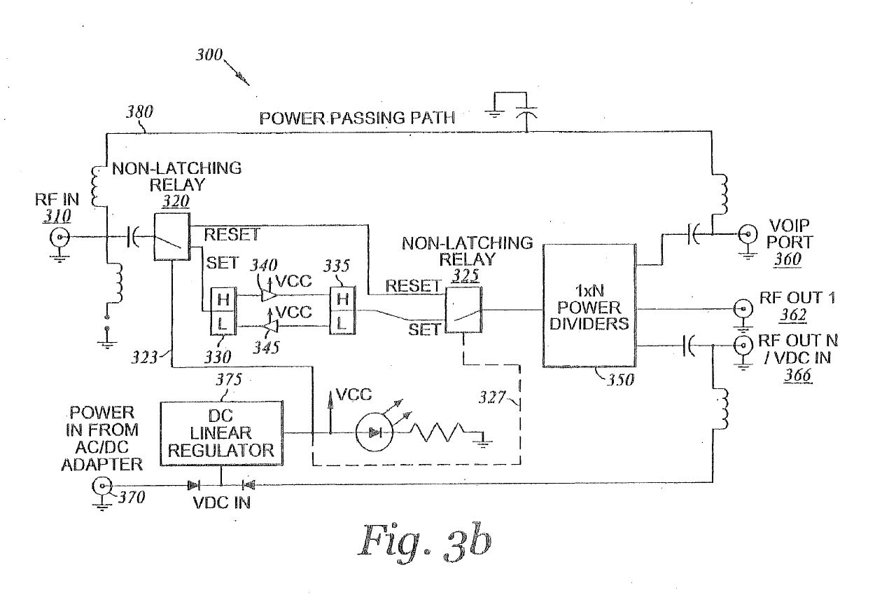

FIG. 3a illustrates a block diagram of a bi-directional RF signal amplifier 300 employing a plurality of non-latching relays for facilitating a non-interruptible communication port 360. As illustrated, amplifier 300 can support a plurality of bi-directional communication ports for sending and receiving RF signals to and from a variety of signal sources and destinations.

Similar to amplifiers 100 and 200 previously discussed herein, amplifier 300 includes a bi-directional RF input port 310 for receiving RF signals from a service provider, or any other appropriate signal source. Input port 310 can also pass output signals in the reverse direction from the amplifier 300 through the port 310 to the service provider or other signal source.

A plurality of bi-directional output ports 360, 362, and 366 can also be provided by amplifier 300 for passing RF signals from the amplifier 300 to one or more devices in communication with the output ports, and vice versa. Similar to amplifiers 100 and 200, it will be appreciated that any appropriate device that may advantageously send and/or receive an RF signal may be placed in communication with one or more of the various output ports of amplifier 300. For example, it is contemplated that telephone, CATV, Internet, VoIP, and/or data communication devices may be placed in such communication where the amplifier 300 is installed in the residence of a subscriber to a service provider. However, it will further be appreciated that any desired combination of these and/or other devices may be used where appropriate.

Signals received through input port 310 can be passed through a first communication path between input port 310 to output ports 360, 362, and/or 366. Specifically, the signals can be fed through a non-latching relay 320 to a high/low diplexer 330 for separating the high frequency input signal from any low frequency output signal incident in the reverse direction. In various embodiments, diplexer 330 can filter the signals in a manner such that signals with frequencies greater than approximately 45-50 MHz are passed as high frequency input signals received from port 310, while signals with frequencies lower than such range are passed in the reverse direction as low frequency output signals received from ports 360, 362, or 366.

The high frequency input signals filtered by diplexer 330 can be amplified by individual amplifier 340, and passed to high/low diplexer 335 where they are combined with the output signals. The recombined signal can then be provided to power dividers 350, where it is distributed to any of ports 360, 362, and/or 366. As illustrated, signals provided to port 360 through a SPDT non-latching relay 325 can further be passed through an attenuator pad 390 for reducing the strength of the amplified signal (approximately 20 dBmV/channel) by approximately 5 dBmV/channel.

Turning now to the reverse signal flow through the first communication path of amplifier 300, signals received by the amplifier 300 from devices in communication with ports 362 and/or 366 can be passed to power dividers 350 where they are combined into a composite output signal. Signals received through port 360 can be passed to power dividers 350 through non-latching relay 325 and attenuator pad 390, and also combined into the composite signal. The output signal can be fed through high/low diplexer 335 for separating the low frequency output signal from any high frequency input signal incident in the forward direction. As previously discussed in relation to diplexer 330, the diplexer 335 can filter the signals such that signals with frequencies greater than approximately 45-50 MHz are passed in the forward direction as high frequency signals received from port 310, while signals with frequencies lower than such range are passed in the reverse direction as low frequency signals received from ports 360, 362, and/or 366.

The low frequency output signals filtered by diplexer 335 can be amplified by individual amplifier 345, and passed to high/low diplexer 330 where they are combined with the input signals. In various embodiments, individual amplifier 345 can optionally be omitted from amplifier 300. The recombined signal can then be provided to SPDT non-latching relay 320 where it is passed to port 310 for output to a service provider or other entity in communication with port 310.

As illustrated, amplifier 300 can further provide a power passing path 380, allowing power to be transmitted between ports 310 and 360.

During normal operation, the amplifier 300 can be powered from a power input port 370 and/or power that is reverse fed through RF OUT N/VDC IN port 366. In a typical installation at a subscriber's residence, it is contemplated that amplifier 300 may be powered by an AC/DC adapter receiving power provided by the residence (for example, 100-230 VAC, 50/60 Hz). As illustrated in FIG. 3, the power received from either power input can be provided to a voltage regulator 375 which supplies an operating voltage VCC to individual amplifiers 340 and/or 345.

In the event that power to voltage regulator 375 is interrupted, voltage regulator 375 will be unable to provide operating voltage VCC to individual amplifiers 340 and/or 345. As a result, individual amplifier 340 will not function to amplify the input signals received through port 310 for proper distribution to the various output ports 360, 362, and/or 366. Similarly, individual amplifier 345 also will not function to amplify the output signals received from ports 360, 362, and/or 366.

As a result, amplifier 300 further provides a second communication path between input port 310 and output port 360. In this regard, a dedicated non-interruptible port 360 can communicate with port 310 through relay 320 and relay 325. As illustrated, amplifier 300 provides a VCC path 323 to relay 320, and a second VCC path 327 to relay 325. When power (i.e. VCC) is interrupted, the relays 320 and 325 will be caused to switch from the normal signal path in the “set” positions, to the non-interruptible signal path in the “reset” positions or vice versa. As a result, using the non-interruptible signal path between ports 310 and 360 through relays 320 and 325, signals can still be passed between a device in communication with port 360 and a service provider in communication with port 310. It will be appreciated that although the second communication path of amplifier 300 does not necessarily amplify the input or output signals, the path can nevertheless permit communication of at least one or more services, such as emergency 911 telephone service.

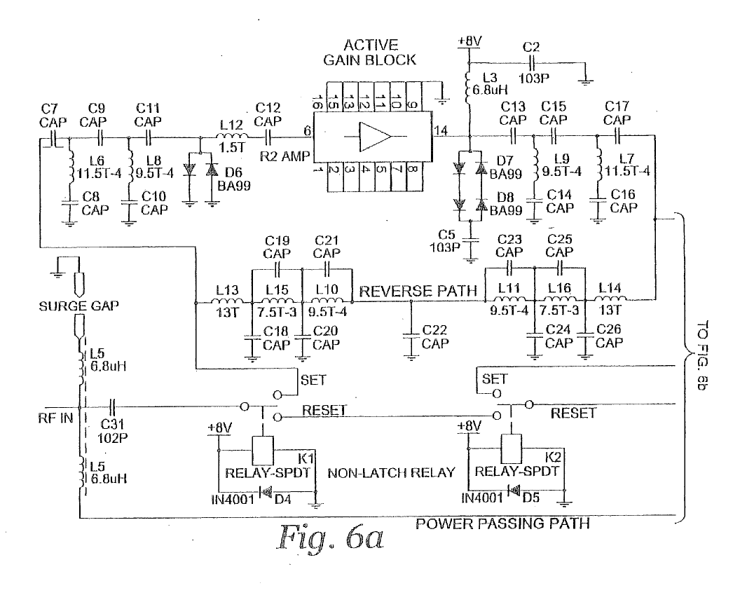

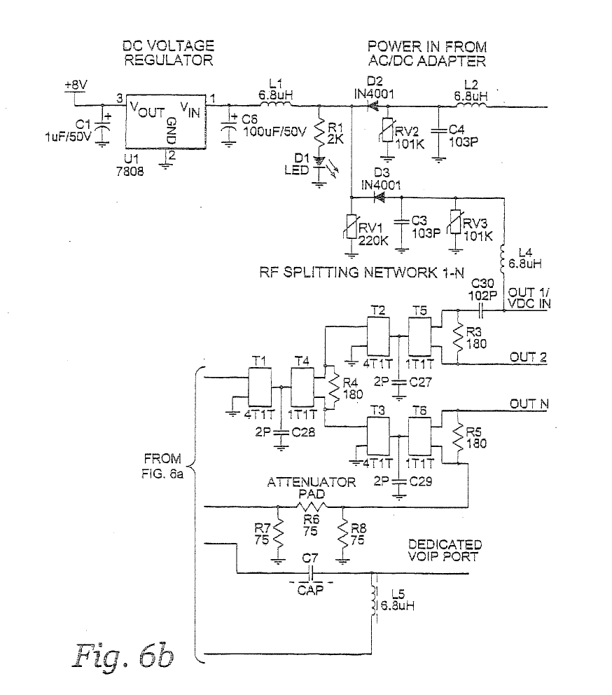

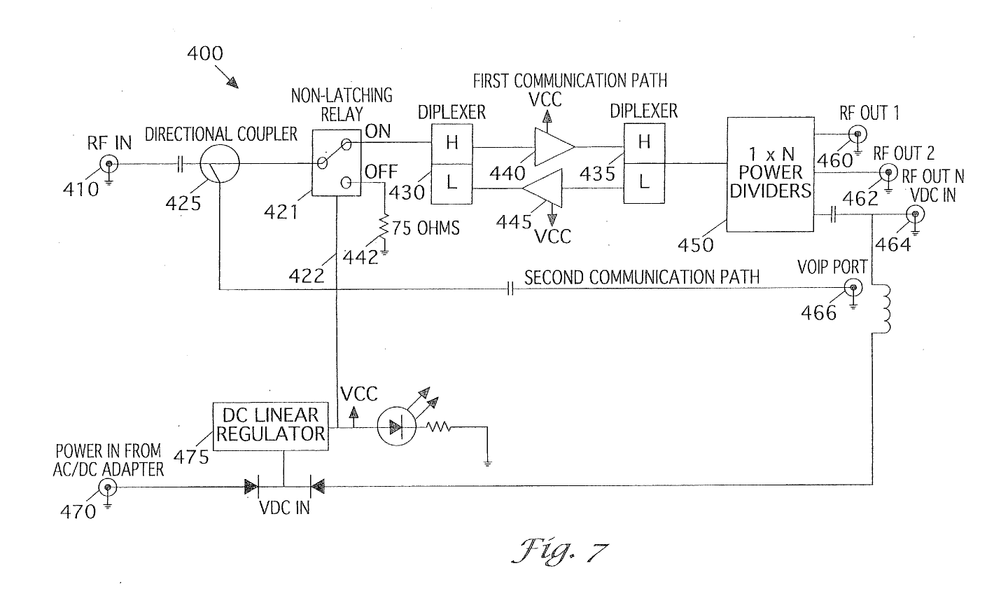

It will be appreciated that the use of the second communication path between ports 310 and 360 can provide a significant advantage in ensuring the availability of communication to at least one communication device in the event of power failure. A communication device in communication with port 360 (such as a VoIP compatible device, or other device) can further be provided with backup battery power to maintain the operation of the communication device. As discussed above, a schematic representation of the amplifier 300 of FIG. 3a is set forth in FIGS. 6a and 6b.

FIG. 3b illustrates a block diagram of an alternate embodiment of bi-directional RF signal amplifier 300. As illustrated, the embodiment of FIG. 3b revises the connections of relay 325, diplexers 335, and power dividers 350. It will be appreciated that the embodiment of FIG. 3b allows each of the output ports 360, 362, and 366 to be switched. It will further be appreciated that a schematic representation of the embodiment of FIG. 3b can be provided through appropriate manipulation of the schematic of FIGS. 6a and 6b.

FIG. 7 is a block diagram of a bi-directional RF signal amplifier 400 employing a non-latching relay 421 and a directional coupler 425 for maintaining a non-interruptible communication port 466. As illustrated, amplifier 400 can support a plurality of bi-directional communication ports for sending and receiving RF signals to and from a variety of signal sources and destinations.

Similar to amplifier 100 previously discussed herein, amplifier 400 includes a bi-directional RF input port 410 for receiving RF signals from a service provider, or any other appropriate signal source. RF input port 410 can also pass output signals in the reverse direction from the amplifier 400 through the port 410 to the service provider or other signal source.

A plurality of bi-directional output ports 460, 462, 464 and 466 can also be provided by amplifier 400 for passing RF signals from the amplifier 400 to one or more devices in communication with the output ports, and vice versa. Similar to amplifier 100, it will be appreciated that any appropriate device that may advantageously send and/or receive an RF signal may be placed in communication with one or more of the various output ports 460, 462, 464 and/or 466 of amplifier 400. For example, it is contemplated that telephone, CATV, Internet, VoIP, and/or data communication devices may be placed in such communication where the amplifier 400 is installed in the residence of a subscriber to a service provider. However, it will further be appreciated that any desired combination of these and/or other devices may be used where appropriate.

Signals received through input port 410 can be passed through a passive directional coupler 425 to first and second communications paths. It will be appreciated that the directional coupler 425 may either evenly or unevenly split the power of the input signals between the first and second communications path, depending on the design of the overall circuit. As shown in FIG. 7, the first communication path includes an SPDT non-latching relay 421, a high/low diplexer 430, a power amplifier 440, a power amplifier 445, a high/low diplexer 435 and 1×N power dividers 450, which components connect the first output of the directional coupler 425 to the output ports 460, 462 and 464. In particular, the signals output by directional coupler 425 to the first communications path are first input to an SPDT non-latching relay 421. When the non-latching relay 421 is in the “ON” or “SET” state, these signals then pass to a high/low diplexer 430 for separating the high frequency input signal from any low frequency output signal incident in the reverse direction. In various embodiments, diplexer 430 can filter the signals in a manner such that signals with frequencies greater than approximately 45-50 MHz are passed as high frequency input signals received from port 410, while signals with frequencies lower than such range are passed in the reverse direction as low frequency output signals received from ports 460, 462, and/or 464.

The high frequency input signals filtered by diplexer 430 can be amplified by individual amplifier 440, and passed to high/low diplexer 435. The output of diplexer 435 is then provided to 1×N power dividers 450, where it is distributed to any of ports 460, 462, and/or 464.

Turning now to the reverse signal flow through the first communication path of amplifier 400, signals received by the amplifier 400 from devices in communication with ports 460, 462 and/or 464 can be passed to power dividers 450 where they are combined into a composite output signal. This composite output signal can be fed through high/low diplexer 435 for separating the low frequency output signal from any high frequency input signal incident in the forward direction. As previously discussed in relation to diplexer 430, the diplexer 435 can filter the signals such that signals with frequencies greater than approximately 45-50 MHz are passed in the forward direction as high frequency signals received from port 410, while signals with frequencies lower than such range are passed in the reverse direction as low frequency signals received from ports 460, 462, and/or 464.

The low frequency output signals filtered by diplexer 435 can be amplified by individual amplifier 445, and passed to high/low diplexer 430 where they are combined with the input signals. In various embodiments, individual amplifier 445 can optionally be omitted from amplifier 400. The recombined signal can then be provided to non-latching relay 421 where it is passed to the RF input port 410 via the directional coupler 425 for output to a service provider or other entity in communication with the RF input port 410. The amplifiers 440 and 445 may have different gains. For example, in some embodiments, amplifier 440 may have about 18 dB gain, while amplifier 445 may have about 15 dB gain. An attenuator (not shown in FIG. 7) may also be provided, for example, between amplifier 445 and diplexer 435.

During normal operation, the amplifier 400 can be powered from a power input port 470 and/or power that is reverse fed through RF OUT N/VDC IN port 464. In a typical installation at a subscriber's residence, it is contemplated that amplifier 400 may be powered by an AC/DC adapter receiving power provided by the residence (for example, 100-230 VAC, 50/60 Hz). As illustrated in FIG. 7, the power received from either power input can be provided to a voltage regulator 475 which supplies an operating voltage VCC to individual amplifiers 440 and/or 445.

In the event that power to voltage regulator 475 is interrupted, voltage regulator 475 will be unable to provide operating voltage VCC to individual amplifiers 440 and/or 445. As a result, individual amplifier 440 will not function to amplify the input signals received through port 410 for proper distribution to the various output ports 460, 462, and/or 464. Similarly, individual amplifier 445 also will not function to amplify the output signals received from ports 460, 462, and/or 464.

Accordingly, amplifier 400 further provides a second, non-interruptible communication path between input port 410 and Voice Over IP (VOIP) output port 466. In particular, as shown in FIG. 7, the signals output by directional coupler 425 to the second communications path may be passed directly to the VOIP output port 466.

Thus, in the embodiment of FIG. 7, the directional coupler 425 is used to split a signal received through input port 410 into two separate components, and delivers the first component of the split signal to RF output ports 460, 462 and 464 via a first communication path and delivers the second component of the split signal to VOIP port 466 via a second communication path. Consequently, even if power is interrupted such that the amplifiers 440 and 445 are rendered inoperable, a second, non-interruptible communication path still exists between RF input port 410 and VOIP port 466 which can be used to support communication of at least one or more services, such as emergency 911 telephone service.

As is also illustrated in FIG. 7, amplifier 400 provides a VCC path 422 to relay 421. When power (i.e., VCC) is interrupted, the relay 421 will be caused to switch from the normal signal path in the “ON” (or “SET”) position, to the “OFF” (or “RESET”) position (or vice versa when power is resumed). The second output port of relay 421 (the “OFF” port) is connected to a matched resistive termination (here a 75 ohm resistor 442). When the power supply is interrupted, the relay 421 senses the interruption and switches from the “ON” position to the “OFF” position. As the OFF position of relay 421 is coupled to the matched resistive termination, both outputs of the directional coupler 425 are matched. As such, signal degradation due to reflections and the like can be reduced or minimized in order to provide acceptable signal quality on the second, non-interruptible communications path.

It will be appreciated that providing a second, non-interruptible communication path between ports 410 and 466 can provide a significant advantage in ensuring the availability of communication to at least one communication device in the event of power failure. A communication device in communication with port 466 (such as a VoIP compatible device, or other device) can further be provided with backup battery power to maintain the operation of the communication device.

As should be clear from the above description, the amplifier 400 of FIG. 7 includes a selective termination circuit that is configured to pass signals between the RF input port and the first RF output port over the first communication path when electrical power is received at the power input and that is further configured to terminate the first communication path to a matched termination when an electrical power feed to the power input is interrupted. In the particular embodiment of FIG. 7, this selective termination circuit comprises a relay that completes the first communication path when electrical power is received at the power input, but terminates the first communication path to a matched termination when an electrical power feed to the power input is interrupted.

Herein, the term “matched termination” is used to refer to a termination that approximately matches the specific transmission paths impedance (in this case 75 ohms), thus being capable of substantially absorbing the possible propagation modes with minimal reflection. The term “resistive termination” is used to refer to a termination that includes at least one purposefully resistive element such as a resistor. By providing such a matched resistive termination in signal amplifier 400, the directional coupler may be configured to have two impedance matched output terminals even when the integrated circuit chip containing the power amplifiers 440 and 445 shuts down for lack of power, and hence reflections that result in return loss, frequency response and/or other signal degradation can be reduced in these circumstances. This may significantly improve the signal quality on the second, non-interruptible communication path (in both the forward and reverse directions) when the first communication path is inactive (i.e., terminated to the matched resistive termination).

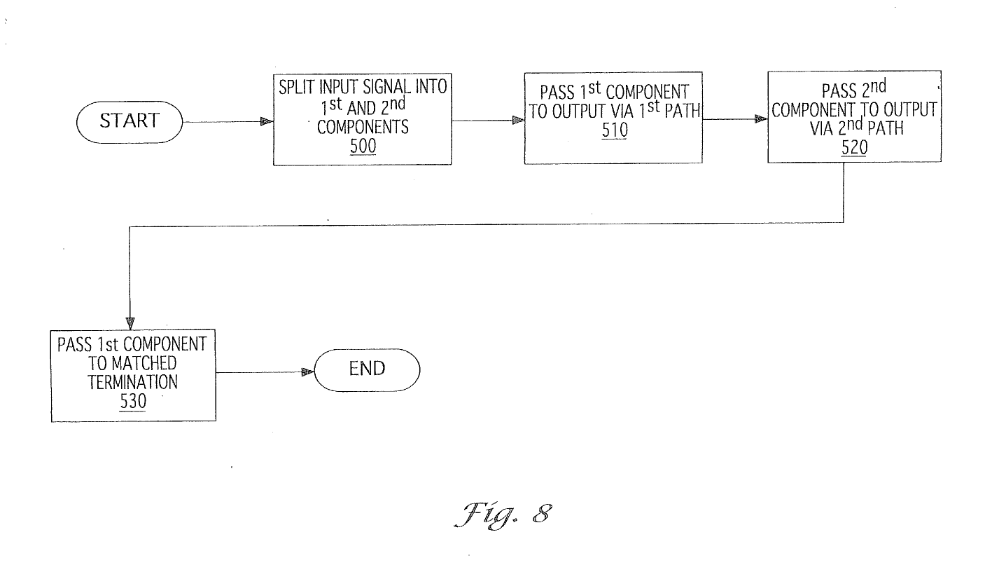

FIG. 8 is a flow chart illustrating methods of providing a non-interruptible communication path through a signal amplifier that includes an RF input port and multiple RF output ports according to embodiments of the present invention. As shown in FIG. 8, pursuant to these methods, a directional coupler may be used to split a signal received at the RF input port into a first signal component and a second signal component (block 500). The signal may comprise, for example, a composite signal from a service provider that includes CATV signals, broadband Internet traffic and/or Internet telephone service traffic. The directional coupler may comprise a splitter that evenly divides the signal energy of the input signal when it splits the signal into the first and second components, or may comprise a weighted directional coupler that provides more of the signal energy to one of the components (e.g., the first component) than to the second component. As is further shown in FIG. 8, the first component is coupled to one or more output ports of the signal amplifier via a first communication path, such as, for example, the first communication path illustrated in FIG. 7 (block 510). Likewise, the second component is coupled to a different output port of the signal amplifier via a second communication path, such as, for example, the second communication path illustrated in FIG. 7 (block 520). At some point, the power feed to the signal amplifier is interrupted. In response to this interruption, the first component of the input signal is routed to a matched resistive termination (block 530).

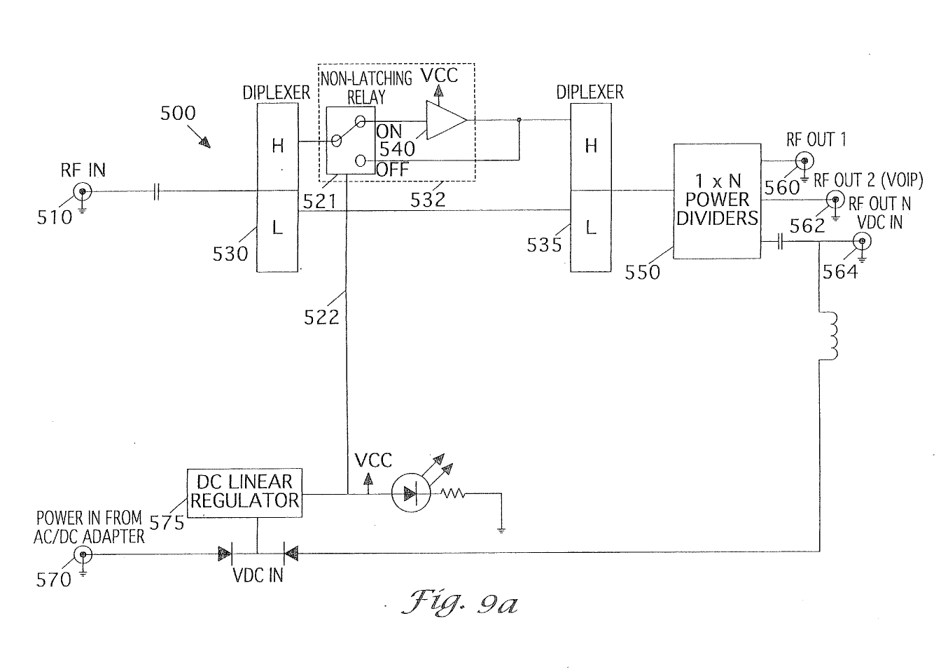

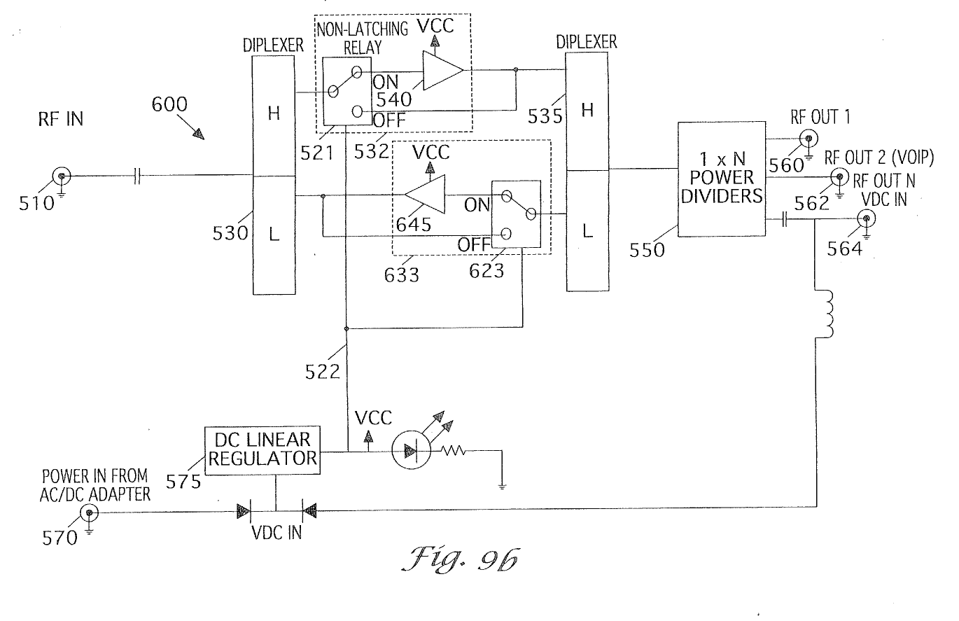

FIG. 9a is a block diagram of a bi-directional RF signal amplifier 500 employing an integrated circuit chip 532 in the forward path that includes a non-latching relay 521 and an amplifier 540 for facilitating a non-interruptible communication port 564. As illustrated, amplifier 500 can support a plurality of bi-directional communication ports for sending and receiving RF signals to and from a variety of signal sources and destinations.

Amplifier 500 includes a bi-directional RF input port 510 for receiving RF signals from a service provider, or any other appropriate signal source. RF input port 510 can also pass output signals in the reverse direction from the amplifier 500 through the port 510 to the service provider or other signal source.

A plurality of bi-directional output ports 560, 562 and 564 can also be provided by amplifier 500 for passing RF signals from the amplifier 500 to one or more devices in communication with the output ports, and vice versa. It will be appreciated that any appropriate device that may advantageously send and/or receive an RF signal may be placed in communication with one or more of the various output ports 560, 562 and/or 564 of amplifier 500. For example, it is contemplated that telephone, CATV, Internet, VoIP, and/or data communication devices may be placed in such communication where the amplifier 500 is installed in the residence of a subscriber to a service provider. However, it will further be appreciated that any desired combination of these and/or other devices may be used where appropriate.

Signals received through input port 510 can be passed directly to a high/low diplexer 530 that separates the high frequency input signal from any low frequency output signal incident in the reverse direction. In various embodiments, diplexer 530 can filter the signals in a manner such that signals with frequencies greater than approximately 45-50 MHz are passed as high frequency input signals received from port 510, while signals with frequencies lower than such range are passed in the reverse direction as low frequency output signals received from ports 560, 562, and/or 564. The high frequency input signals filtered by diplexer 530 are passed to an SPDT non-latching relay 521. When the non-latching relay 521 is in the “ON” or “SET” state, these signals then pass to a power amplifier 540, then to a high/low diplexer 535 and 1×N power dividers 550 where the signals are passed to the output ports 560, 562 and 564.

Turning now to the reverse signal flow through amplifier 500, signals received by the amplifier 500 from devices in communication with ports 560, 562 and/or 564 can be passed to power dividers 550 where they are combined into a composite output signal. This composite output signal can be fed through high/low diplexer 535 for separating the low frequency output signal from any high frequency input signal incident in the forward direction. As previously discussed in relation to diplexer 530, the diplexer 535 can filter the signals such that signals with frequencies greater than approximately 45-50 MHz are passed in the forward direction as high frequency signals received from port 410, while signals with frequencies lower than such range are passed in the reverse direction as low frequency signals received from ports 560, 562, and/or 564.

The low frequency output signals filtered by diplexer 535 are passed without amplification to high/low diplexer 530 where they are combined with the input signals. The recombined signal can then be passed to the RF input port 510 for output to a service provider or other entity in communication with the RF input port 510.

During normal operation, the amplifier 500 can be powered from a power input port 570 and/or power that is reverse fed through RF OUT N/VDC IN port 564. In a typical installation at a subscriber's residence, it is contemplated that amplifier 500 may be powered by an AC/DC adapter receiving power provided by the residence (for example, 100-230 VAC, 50/60 Hz). As illustrated in FIG. 9a, the power received from either power input can be provided to a voltage regulator 575 which supplies an operating voltage VCC to individual amplifier 540.

In the event that power to voltage regulator 575 is interrupted, voltage regulator 575 will be unable to provide operating voltage VCC to individual amplifier 540. As a result, individual amplifier 540 will not function to amplify the input signals received through port 510 for proper distribution to the various output ports 560, 562, and/or 564.

Accordingly, amplifier 500 further provides a second, non-interruptible communication path between input port 510 and the output ports 560, 562 and, in particular, Voice Over IP (VOIP) output port 564. More particularly, when power (i.e., VCC) is interrupted, the relay 521 will be caused to switch from the normal signal path in the “ON” (or “SET”) position, to the “OFF” (or “RESET”) position (or vice versa when power is resumed). The second output port of relay 521 (the “OFF” port) is connected so as to bypass the amplifier 540, thus providing a second, non-interruptible communications path between diplexer 530 and diplexer 535. When the power supply is interrupted, the relay 521 senses the interruption and switches from the “ON” position to the “OFF” position, thereby activating the non-interruptible (and non-amplified) communications path. Consequently, even if power is interrupted such that the amplifier 540 is rendered inoperable, a second, non-interruptible communication path still exists between RF input port 510 and VOIP port 564 which can be used to support communication of at least one or more services, such as emergency 911 telephone service. Note that in the embodiment of FIG. 9a, any of the output ports may be the VOIP port (i.e., it does not have to be output port 564).

It will be appreciated that providing a second, non-interruptible communication path between ports 510 and 564 can provide a significant advantage in ensuring the availability of communication to at least one communication device in the event of power failure. A communication device in communication with port 564 (such as a VoIP compatible device, or other device) can further be provided with backup battery power to maintain the operation of the communication device.

In some embodiments, the non-latching relay 521 and the amplifier 540 may be implemented on a single integrated circuit chip 532. It will also be appreciated that in some embodiments, the integrated circuit chip 532 may include one or more additional relays. By way of example, the integrated circuit chip 532 may include a second relay that together with relay 521 physically disconnect the amplifier 540 from the electrical path. this configuration may further improve the impedance match of the bypass trace (i.e., the trace from the second output of relay 521 to the diplexer 535).

FIG. 9b is a block diagram of a bi-directional RF signal amplifier 600 that includes a first integrated circuit chip 532 in the forward path that includes a non-latching relay 521 and an amplifier 540, and a second integrated circuit chip 633 in the reverse path that includes a non-latching relay 623 and an amplifier 645 for facilitating a non-interruptible communication port 564. The RF signal amplifier 600 may be nearly identical to the RF signal amplifier 500 of FIG. 9a, except that the RF signal amplifier 600 employs a second integrated circuit chip 633 in the reverse path that includes a non-latching relay 623 and an amplifier 645. Consequently, circuit elements of RF signal amplifier 600 that are identical to the corresponding circuit elements of RF signal amplifier 500 of FIG. 9a are given like reference numerals, and these circuit elements and the operation thereof will not be described further herein.

As noted above, the difference between RF signal amplifier 600 of FIG. 9b and the RF signal amplifier 500 of FIG. 9a is the inclusion of a second integrated circuit chip 633 in the reverse path. This second integrated circuit chip 633 has a non-latching relay 623 and an amplifier 645. During normal operation, the amplifier 645 is powered by VCC and the non-latching relay 623 is in the “ON” or “SET” state so that signals in the reverse path are passed through power amplifier 645. However, if power to voltage regulator 575 is interrupted, the relay 623 senses the interruption and switches from the “ON” position to the “OFF” position. The second output port of relay 623 (the “OFF” port) is connected so as to bypass the amplifier 645, thus providing a second, non-interruptible communications path in the reverse direction between diplexer 535 and diplexer 530. Thus, the RF signal amplifier 600 provides amplification in the reverse direction during normal operation, while still providing non-interruptible (and non-amplified) communications paths in both the forward and reverse directions when power is interrupted.

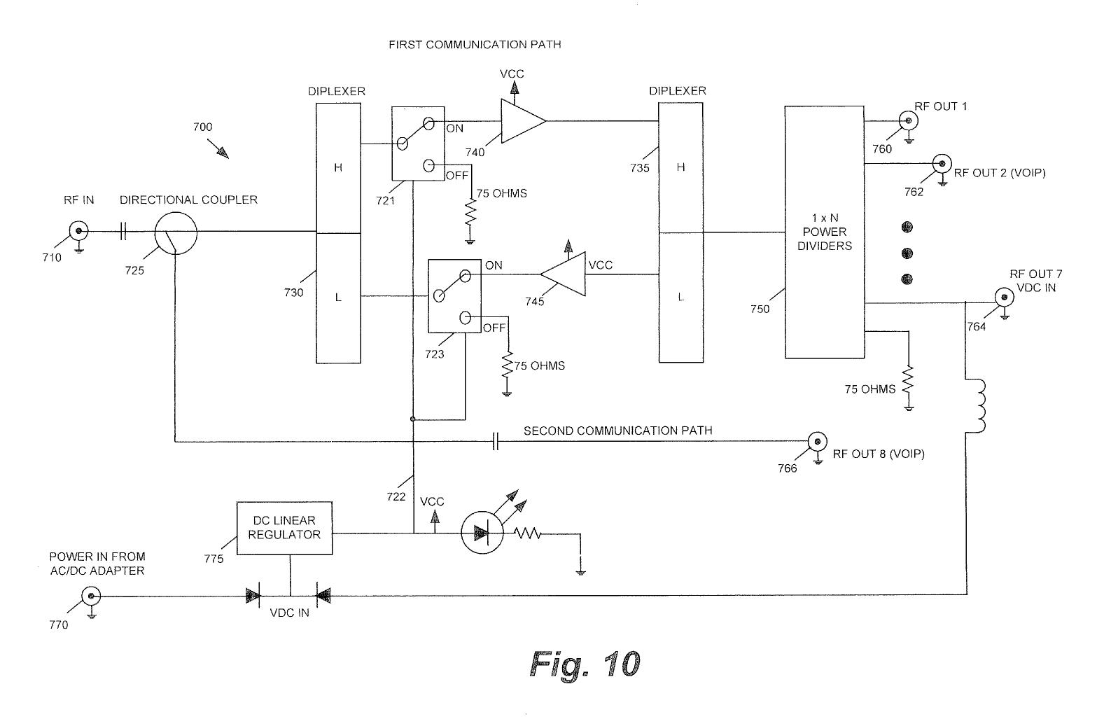

FIG. 10 is a block diagram of a bi-directional RF signal amplifier 700 according to further embodiments of the present invention. The bi-directional RF signal amplifier 700 includes a directional coupler 725 and two integrated circuit RF relay chips 721, 723. As illustrated, amplifier 700 can support a plurality of bi-directional communication ports for sending and receiving RF signals to and from a variety of signal sources and destinations.

Similar to amplifier 100 previously discussed herein, amplifier 700 includes a bi-directional RF input port 710 for receiving RF signals from a service provider, or any other appropriate signal source. RF input port 710 can also pass output signals in the reverse direction from the amplifier 700 to the service provider or other signal source.

A plurality of bi-directional output ports 760, 762, 764 and 766 are also provided for passing RF signals from the amplifier 700 to one or more devices in communication with the output ports, and vice versa. Similar to amplifier 100, it will be appreciated that any appropriate device that may advantageously send and/or receive an RF signal may be placed in communication with one or more of the various output ports 760, 762, 764 and/or 766 of amplifier 700. For example, it is contemplated that telephone, CATV, Internet, VoIP, and/or data communication devices may be placed in such communication where the amplifier 700 is installed in the residence of a subscriber to a service provider. However, it will further be appreciated that any desired combination of these and/or other devices may be used where appropriate.

Signals received through input port 710 can be passed through a passive directional coupler 725 to first and second communications paths. It will be appreciated that the directional coupler 725 may either evenly or unevenly split the power of the input signals between the first and second communications paths, depending on the design of the overall circuit. As shown in FIG. 10, the first communication path includes high/low diplexer 730, an integrated circuit RF relay chip 721, a power amplifier 740, an integrated circuit RF relay chip 723, a power amplifier 745, a high/low diplexer 735 and 1×N power dividers 750, which components connect the first output of the directional coupler 725 to the output ports 760, 762 and 764 (which are three of the exemplary seven output ports attached to the 1×N power divider 750 of the embodiment of FIG. 10). In particular, the signals output by directional coupler 725 in the forward direction to the first communications path are first input to the high/low diplexer 730 for separating the high frequency input signal from any low frequency output signal incident in the reverse direction. In various embodiments, diplexer 730 can filter the signals in a manner such that signals with frequencies greater than approximately 45-50 MHz are passed as high frequency input signals received from port 710, while signals with frequencies lower than such range are passed in the reverse direction as low frequency output signals received from ports 760, 762, and/or 764.

The high frequency input signals filtered by diplexer 730 are passed to integrated circuit chip RF relay 721. When the relay 721 is in the “ON” or “SET” state, these signals then pass to an individual amplifier 740 for amplification, and then are passed from the output of the amplifier 740 to high/low diplexer 735. The output of diplexer 735 is then provided to 1×N power dividers 750, where it is distributed to any of ports 760, 762, and/or 764. In the particular embodiment depicted in FIG. 10, the 1×N power dividers 750 may be a 1×8 power divider. Seven of the outputs of 1×N power divider 750 are connected to respective of first through seventh RF output ports, while the eighth output is terminated to ground via a 75 ohm resistor.

Turning now to the reverse signal flow through the first communication path of amplifier 700, signals received by the amplifier 700 from devices in communication with ports 760, 762 and/or 764 can be passed to power dividers 750 where they are combined into a composite output signal. This composite output signal can be fed through high/low diplexer 735 for separating the low frequency output signal from any high frequency input signal incident in the forward direction. As previously discussed in relation to diplexer 730, the diplexer 735 can filter the signals such that signals with frequencies greater than approximately 45-50 MHz are passed in the forward direction as high frequency signals received from port 710, while signals with frequencies lower than such range are passed in the reverse direction as low frequency signals received from ports 760, 762, and/or 764.

The low frequency output signals filtered by diplexer 735 can be amplified by individual amplifier 745, and passed to integrated circuit chip RF relay 723. When the relay 723 is in the “ON” or “SET” state, these signals then pass to high/low diplexer 730 where they are combined with the input signals. The recombined signal can then be passed to the RF input port 710 via the directional coupler 725 for output to a service provider or other entity in communication with the RF input port 710. The amplifiers 740 and 745 may have different gains. For example, in some embodiments, amplifier 740 may have about 18 dB gain, while amplifier 745 may have about 15 dB gain. An attenuator (not shown in FIG. 10) may also be provided, for example, between amplifier 745 and diplexer 735. It will also be appreciated that in some embodiments, individual amplifier 745 and/or relay 723 can optionally be omitted from amplifier 700.

During normal operation, the amplifier 700 can be powered from a power input port 770 and/or power that is reverse fed through, for example, RF OUT 7/VDC IN port 764. In a typical installation at a subscriber's residence, it is contemplated that amplifier 700 may be powered by an AC/DC adapter receiving power provided by the residence (for example, 100-230 VAC, 50/60 Hz). As illustrated in FIG. 10, the power received from either power input can be provided to a voltage regulator 775 which supplies an operating voltage VCC to individual amplifiers 740 and/or 745.

In the event that power to voltage regulator 775 is interrupted, voltage regulator 775 will be unable to provide operating voltage VCC to individual amplifiers 740 and/or 745. As a result, individual amplifier 740 will not function to amplify the input signals received through port 710 for proper distribution to the various output ports 760, 762, and/or 764. Similarly, individual amplifier 745 also will not function to amplify the output signals received from ports 760, 762, and/or 764.

Accordingly, amplifier 700 further provides a second, non-interruptible communication path between input port 710 and Voice Over IP (VOIP) output port 766. In particular, as shown in FIG. 10, the signals output by directional coupler 725 to the second communications path may be passed directly to the VOIP output port 766.

Thus, in the embodiment of FIG. 10, the directional coupler 725 is used to split a signal received through input port 710 into two separate components, and delivers the first component of the split signal to RF output ports 760, 762 and 764 via a first communication path and delivers the second component of the split signal to VOIP port 766 via a second communication path. Consequently, even if power is interrupted such that the amplifiers 740 and 745 are rendered inoperable, a second, non-interruptible communication path still exists between RF input port 710 and VOIP port 766 which can be used to support communication of at least one or more services, such as emergency 911 telephone service.

As is also illustrated in FIG. 10, amplifier 700 provides a VCC path 722 to relays 721 and 723. When power (i.e., VCC) is interrupted, the relays 721, 723 will each switch from the normal signal path in the “ON” (or “SET”) position, to the “OFF” (or “RESET”) position (or vice versa when power is resumed). The respective second output ports of relay 721 and 723 (the “OFF” ports) are each connected to a matched resistive termination (here a 75 ohm resistor). When the power supply is interrupted, the relays 721 and 723 sense the power supply interruption and they each switch from the “ON” position to the “OFF” position. As the OFF positions of relays 721 and 723 are each coupled to a matched resistive termination, both outputs of the directional coupler 725 are matched. As such, signal degradation due to reflections and the like can be reduced or minimized in order to provide acceptable signal quality on the second, non-interruptible communications path.

In some embodiments, the relay 721 and the amplifier 740 may be implemented on a single integrated circuit chip, and/or the relay 723 and the amplifier 745 may be implemented on a single integrated circuit chip. It will also be appreciated that in some embodiments, the relays 721 and 723 and the power amplifiers 740, 745 may all be implemented on a single integrated circuit chip.

It will be appreciated that providing a second, non-interruptible communication path between ports 710 and 766 can provide a significant advantage in ensuring the availability of communication to at least one communication device in the event of power failure. A communication device in communication with port 766 (such as a VoIP compatible device, or other device) can further be provided with backup battery power to maintain the operation of the communication device.

The bi-directional RF signal amplifier 700 of FIG. 10 may provide improved performance in applications where significant signal power is carried along the reverse path. In particular, in embodiments such as the embodiment of FIG. 7 where the relay 421 is located in a common path that carries signals in both the forward and reverse directions, distortion by-product signals may be generated in the relay 421. To the extent that these distortion by-product signals are within the frequency range passed by the high side of the first diplexer 430, the distortion by-product signals will pass to the first amplifier 440 where they are amplified and passed to the RF output ports 460, 462, 464. However, in the embodiment of FIG. 10, the first and second relays 721, 723 are located between the first and second diplexers 730, 735. Consequently, any distortion by-product signals generated in the relay 723 that fall within the frequency range passed by the high side of the first diplexer 730 will be isolated by the diplexer 730, thereby protecting the forward path from distortion by-product signals generated in the reverse path.

The foregoing disclosure is not intended to limit the present invention to the precise forms or particular fields of use disclosed. It is contemplated that various alternate embodiments and/or modifications to the present invention, whether explicitly described or implied herein, are possible in light of the disclosure. For example, any number of RF output ports may be supported by the various amplifier embodiments discussed herein.

That which is claimed is:

1. A bi-directional RF signal amplifier, comprising
an RF input port;
a first RF output port;
a second RF output port;
a directional coupler having an input that is coupled to the RF input port, a first output and a second output, wherein the second output of the directional coupler is connected to the second RF output port via a non-interruptible communication path;
a first switching device having an input, a first output and a second output, wherein the second output of the first switching device is coupled to a first matched termination;
a first diplexer that is coupled between the first output of the directional coupler and the input of the first switching device;
a first power amplifier having an input that is coupled to the first output of the first switching device;
a second diplexer that is coupled between an output of the first power amplifier and the first RF output port; and
a power input for receiving electrical power;
wherein the first switching device is configured to pass signals received at the input to the first switching device to the first output of the first switching device when electrical power is received at the power input and that is further configured to terminate signals received at the input to the first switching device through the second output of the first switching device when an electrical power feed to the power input is interrupted.

2. The bi-directional RF signal amplifier of claim 1, further comprising a second switching device and a second power amplifier coupled in series between the first and second diplexers.

3. The bi-directional RF signal amplifier of claim 2, wherein the second switching device has an input that is coupled to an output of the second power amplifier, a first output that is coupled to the first diplexer and a second output that is coupled to a second matched termination.

4. The bi-directional RF signal amplifier of claim 4, wherein the first matched termination comprises a first resistor that is terminated to a ground voltage and wherein the second matched termination comprises a second resistor that is terminated to a ground voltage.

5. The bi-directional RF signal amplifier of claim 4, further comprising a power regulation circuit that receives electrical power from the power input and that outputs a power supply voltage, wherein the power supply voltage is coupled to the first power amplifier, the second power amplifier, the first switching device and the second switching device.

6. The bi-directional RF signal amplifier of claim 5, wherein the directional coupler splits an input signal evenly between its first output and its second output.

7. The bi-directional RF signal amplifier of claim 5, wherein the directional coupler splits an input signal unevenly so as to pass more signal energy to its first output than is passed to its second output.

8. The bi-directional RF signal amplifier of claim 5, further comprising a power dividing circuit having an input and a plurality of outputs that is between the second diplexer and the first RF output port, wherein the first RF output port is connected to one of the plurality of outputs of the power dividing circuit.

9. The bi-directional RF signal amplifier of claim 5, wherein the second RF output port comprises a voice-over-IP RF output port.

10. The bi-directional RF signal amplifier of claim 5, wherein a first gain of the first power amplifier is greater than a second gain of the second power amplifier.

11. The bi-directional RF signal amplifier of claim 9, wherein the second switching device and the second power amplifier are coupled between a low port of the first diplexer and a low port of the second diplexer, and wherein the first switching device and the first power amplifier are coupled between a high port of the first diplexer and a high port of the second diplexer.

12. The bi-directional RF signal amplifier of claim 11, wherein the first output port of the directional coupler is coupled to a common port of the first diplexer, and wherein the power dividing circuit is coupled to a common port of the second diplexer.

13. An RF signal amplifier, comprising:
an RF input port;
an RF output port;
a switching device having an input that is coupled to the RF input port, a first output and a second output, wherein the second output of the switching device is coupled to a matched termination;
a first power amplifier coupled between the first output of the switching device and the RF output port; and
a power input for receiving electrical power;
wherein the switching device is configured to couple the RF input port to the first output of the switching device when electrical power is received at the power input and to couple the RF input port to the second output of the switching device when an electrical power feed to the power input is interrupted.

14. The RF signal amplifier of claim 13, wherein an input of the first power amplifier is coupled to the first output of the switching device, and an output of the first power amplifier is coupled to the RF output port.

15. The RF signal amplifier of claim 13, wherein an input of the first power amplifier is coupled to the RF output port, and an output of the first power amplifier is coupled to the first output of the switching device.

16. The RF signal amplifier of claim 13, further comprising a first diplexer that is coupled between the first output of the switching device and an input to the first power amplifier.

17. The RF signal amplifier of claim 16, further comprising a second diplexer that is coupled between an output of the first power amplifier and the RF output port.

18. The RF signal amplifier of claim 17, further comprising a second power amplifier having an input that is coupled to the second diplexer and an output that is coupled to the first diplexer.

19. The RF signal amplifier of claim 13, wherein the first matched termination comprises a resistor that is terminated to a ground voltage.

20. The RF signal amplifier of claim 13, further comprising a power regulation circuit that receives electrical power from the power input and that outputs a power supply voltage, wherein the power supply voltage is coupled to the power amplifier and the switching device.

21. The RF signal amplifier of claim 17, wherein the first power amplifier comprise a first communications path between the first diplexer and the second diplexer, the RF signal amplifier further comprising a second communications path between the first diplexer and the second diplexer.

22. The RF signal amplifier of claim 21, further comprising a second power amplifier that is part of the second communications path between the first diplexer and the second diplexer.

23. The RF signal amplifier of claim 21, wherein the second communications path is a non-amplified communications path between the first diplexer and the second diplexer.

24. A method of automatically terminating an RF signal amplifier, the method comprising:
coupling an input of the RF signal amplifier to a cable television network, where the RF signal amplifier comprises a power amplifier and a switching device having a switch input that is coupled to the cable television network, a first switch output that is coupled to the power amplifier and a second switch output that is coupled to a matched termination;
automatically switching the switching device to connect the switch input from the first switch output to the second switch output in response to an electrical power feed to the RF signal amplifier being interrupted.

25. The method of claim 24, further comprising automatically switching the switching device to connect the switch input from the second switch output to the first switch output in response to the electrical power feed to the RF signal amplifier being restored.

26. The method of claim 25, wherein the first matched termination comprises a resistor that is terminated to a ground voltage.

27. The method of claim 25, wherein the power amplifier comprises a first power amplifier and the first switch output is coupled to an input to the first power amplifier, and wherein the RF signal amplifier further comprises a second power amplifier having an output that is coupled to the first switch output.

28. The method of claim 27, wherein the RF signal amplifier further comprises a first diplexer that is coupled between the first switch output and the first and second power amplifiers.
